(19) United States
(12) Patent Application Publication
(10) Pub. No.: US 2021/0335899 A1
(43) Pub. Date: Oct. 28, 2021

(54) ORGANIC LIGHT-EMITTING DIODE DISPLAY

(71) Applicant: SHENZHEN CHINA STAR OPTOELECTRONICS SEMICONDUCTOR DISPLAY TECHNOLOGY CO., LTD., Shenzhen Guangdong (CN)

(72) Inventor: Ming XU, Shenzhen Guangdong (CN)

(21) Appl. No.: 16/614,376

(22) PCT Filed: Nov. 4, 2019
(86) PCT No.: PCT/CN2019/115271

§ 371 Date: Nov. 18, 2019

(30) Foreign Application Priority Data
May 31, 2019 (CN) 201910466602.9

(51) Int. Cl. H01L 27/32; H01L 51/52

(52) U.S. Cl. CPC H01L 27/326; H01L 2251/5315; H01L 51/5271

(57) ABSTRACT

An organic light-emitting diode display is provided, including a transparent substrate, a top emission-type light-emitting device disposed on the transparent substrate and including a first thin film transistor, and a bottom emission-type light-emitting device disposed on the transparent substrate and including a second thin film transistor. An orthographic projection of the second thin film transistor of the bottom emission-type light-emitting device on the top emission-type light-emitting device overlaps at least a portion of the first thin film transistor.

### FIELD OF DISCLOSURE

The present disclosure relates to the field of display technologies, and more particularly to an organic light-emitting diode display.

### BACKGROUND

Organic light-emitting diode (OLED) displays have broad application prospects. OLED displays emit light by injecting and recombining carriers by driving an organic semiconductor luminescent material under an electric field. According to driving method, OLED displays can be divided into two categories including a passive driving and an active driving, i.e., direct addressing and thin film transistor (TFT) matrix addressing. Active-driven OLED displays are also referred to as active-matrix organic light-emitting diode (AMOLED) displays. Each lighting unit is independently controlled by TFT addressing. For large screen and high resolution displays, active-matrix driving method is often used.

OLED displays can be classified into two types including a bottom emission-type and a top emission-type according to the different emissions of the light. The light emitted by the bottom emission-type OLED is emitted from one side of an underlay substrate, and the light of the top emission-type OLED display is emitted from a top. However, if the OLED display of the bottom emission-type structure is used, an opening area of the OLED display should be disposed away from an area of the TFT, which causes a serious reduction in an aperture of the panel and affects a display performance. On the other hand, it is limited by pixel definition areas of a backplane, fine metal mask openings, and engineering factors such as an alignment accuracy, even if the OLED display of the top emission-type structure is used, the aperture of the display panel is much less than 80%. Therefore, the existing AMOLED display products still have not fully utilized a potential of OLED displays.

Accordingly, it is necessary to provide an OLED device having a high aperture to solve the technical problem in the prior art.

### SUMMARY OF DISCLOSURE

In order to solve technical problems mentioned above, an object of the present disclosure is to provide an OLED device, which integrates structures of a bottom emission-type and a top emission-type, effective light-emitting areas are alternately arranged, thereby increasing a ratio of the effective light-emitting areas and increasing an aperture of the display panel.

In order to achieve the object described above, the present disclosure provides an organic light-emitting diode display, including: a transparent substrate including a first side and a second side opposite to the first side, a top emission-type light-emitting device disposed on the first side of the transparent substrate, and a bottom emission-type light-emitting device disposed on the second side of the transparent substrate. The top emission-type light-emitting device includes: a first thin film transistor, a first passivation layer disposed on the first thin film transistor, a first reflective layer disposed on the first passivation layer and electrically connected to the first thin film transistor, a first organic light-emitting diode layer disposed on the first reflective layer, and a first transparent conductive layer disposed on the first organic light-emitting diode layer. The bottom emission-type light-emitting device includes: a second thin film transistor, a second passivation layer disposed on the second thin film transistor, a second transparent conductive layer disposed on the second passivation layer and electrically connected to second thin film transistor, a second organic light-emitting diode layer disposed on the second transparent conductive layer, and a second reflective layer disposed on the second organic light-emitting diode layer. An orthographic projection of the second thin film transistor of the bottom emission-type light-emitting device on the top emission-type light-emitting device overlaps at least a portion of the first thin film transistor.

In one preferable embodiment of the present disclosure, a light emission direction of the top emission-type light-emitting device is the same as that of the bottom emission-type light-emitting device.

In one preferable embodiment of the present disclosure, the first reflective layer serves as an anode of the top emission-type light-emitting device, and the first transparent conductive layer serves as a cathode of the top emission-type light-emitting device.

In one preferable embodiment of the present disclosure, the organic light-emitting also includes a plurality of top emission-type light-emitting devices and a first pixel definition layer disposed between two adjacent top emission-type light-emitting devices.

In one preferable embodiment of the present disclosure, the second transparent conductive layer serves as an anode of the bottom emission-type light-emitting device, and the second reflective layer serves as a cathode of the bottom emission-type light-emitting device.

In one preferable embodiment of the present disclosure, an orthographic projection of the second thin film transistor on the transparent substrate is prevented from mutually overlapping on another orthographic projection of the second transparent conductive layer on the transparent substrate, or they only overlap each other in a portion that are connected.

In one preferable embodiment of the present disclosure, the organic light-emitting diode display also includes a plurality of bottom emission-type light-emitting devices and a second pixel definition layer disposed between two adjacent bottom emission-type light-emitting devices.

In one preferable embodiment of the present disclosure, an orthographic projection of the first reflective layer on the transparent substrate is prevented from mutually overlapping on another orthographic projection of the second reflective layer on the transparent substrate.

The present disclosure also provides an organic light-emitting diode display includes: a transparent substrate including a first side and a second side opposite to the first side, a top emission-type light-emitting device disposed on the first side of the transparent substrate, and a bottom emission-type light-emitting device disposed on the second side of the transparent substrate. The top emission-type light-emitting device includes a first thin film transistor. The bottom emission-type light-emitting device includes a second thin film transistor. An orthographic projection of the second thin film transistor of the bottom emission-type light-emitting device on the top emission-type light-emitting device overlaps at least a portion of the first thin film transistor.

In one preferable embodiment of the present disclosure, a light emission direction of the top emission-type light-emitting device is the same as that of the bottom emission-type light-emitting device.

In one preferable embodiment of the present disclosure, the top emission-type light-emitting device also includes: a first passivation layer disposed on the first thin film transistor, a first reflective layer disposed on the first passivation layer and electrically connected to the first thin film transistor, a first organic light-emitting diode layer disposed on the first reflective layer, and a first transparent conductive layer disposed on the first organic light-emitting diode layer.

In one preferable embodiment of the present disclosure, the first reflective layer serves as an anode of the top emission-type light-emitting device, and the first transparent conductive layer serves as a cathode of the top emission-type light-emitting device.

In one preferable embodiment of the present disclosure, the organic light-emitting diode display also includes a plurality of top emission-type light-emitting devices and a first pixel definition layer disposed between two adjacent top emission-type light-emitting devices.

In one preferable embodiment of the present disclosure, the bottom emission-type light-emitting device also includes: a second passivation layer disposed on the second thin film transistor, a second transparent conductive layer disposed on the second passivation layer and electrically connected to second thin film transistor, a second organic light-emitting diode layer disposed on the second transparent conductive layer, and a second reflective layer disposed on the second organic light-emitting diode layer.

In one preferable embodiment of the present disclosure, the second transparent conductive layer serves as an anode of the bottom emission-type light-emitting device, and the second reflective layer serves as a cathode of the bottom emission-type light-emitting device.

In one preferable embodiment of the present disclosure, an orthographic projection of the second thin film transistor on the transparent substrate is prevented from mutually overlapping on another orthographic projection of the second transparent conductive layer on the transparent substrate, or they only overlap each other in a portion that are connected.

In one preferable embodiment of the present disclosure, the organic light-emitting diode display also includes a plurality of bottom emission-type light-emitting devices and a second pixel definition layer disposed between two adjacent bottom emission-type light-emitting devices.

In one preferable embodiment of the present disclosure, the top emission-type light-emitting device also includes a first reflective layer, and the bottom emission-type light-emitting device also includes a second reflective layer, and an orthographic projection of the first reflective layer on the transparent substrate is prevented from mutually overlapping on another orthographic projection of the second reflective layer on the transparent substrate.

In comparison to prior art, the present disclosure forms an organic light-emitting diode display into an AMOLED display panel integrating structures of a top emission-type device and a bottom emission-type device. When the organic light-emitting diode display is in operation, a top emission-type light-emitting device and a bottom emission-type light-emitting device on both sides of a transparent substrate emit light in the same direction. The organic light-emitting diode display of the present disclosure has a higher aperture and a doubling of pixel density as compared to the prior art.

### BRIEF DESCRIPTION OF DRAWINGS

FIG. 1 is a schematic diagram showing an organic light-emitting diode display according to a preferred embodiment of the present disclosure.

### DETAILED DESCRIPTION

The structure and the technical means adopted by the present disclosure to achieve the above and other objects can be best understood by referring to the following detailed description of the preferred embodiments and the accompanying drawings.

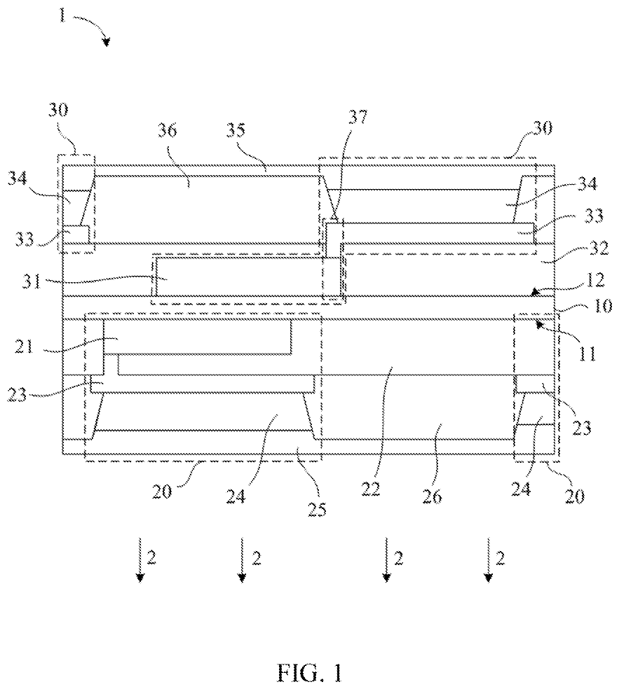

Please refer to FIG. 1, which is a schematic diagram showing an organic light-emitting diode display 1 according to a preferred embodiment of the present disclosure. FIG. 1 shows only a partial section of the organic light-emitting diode display 1. The organic light-emitting diode display 1 is an active matrix organic light emitting diode (AMOLED) display that combines structures of a top emission-type device and a bottom emission-type device. The organic light-emitting diode display 1 includes a transparent substrate 10, a plurality of top emission-type light-emitting devices 20, and a plurality of bottom emission-type light-emitting devices 30. The transparent substrate 10 includes a first side 11 and a second side 12. The first side 11 is opposite to the second side 12. The plurality of top emission-type light-emitting devices 20 are disposed apart from each other on the first side 11 of the transparent substrate 10. The plurality of bottom emission-type light-emitting devices 30 are disposed apart from each other on the second side 12 of the transparent substrate 10. It should be noted that each top emission-type light-emitting device 20 or each bottom emission-type light-emitting device 30 represents one pixel unit. Effective light-emitting areas of the plurality of top emission-type light-emitting devices 20 and the plurality of bottom emission-type light-emitting devices 30 are alternately arranged, so that light from either the top emission-type light-emitting device 20 or the bottom emission-type light-emitting device 30 can emit to an outside. Preferably, material of the transparent substrate 10 includes a transparent material such as glass, polyethylene terephthalate (PET) or the like.

As shown in FIG. 1, each top emission-type light-emitting device 20 includes a first thin film transistor 21, a first passivation layer 22, a first reflective layer 23, a first organic light-emitting diode layer 24, a first transparent conductive layer 25, and a first pixel definition layer 26. The first thin film transistor 21 is disposed on the first side 11 of the transparent substrate 10. The first passivation layer 22 is disposed on the first thin film transistor 21 and the transparent substrate 10. The first reflective layer 23 and the first pixel definition layer 26 are both disposed on the first passivation layer 22, and the first reflective layer 23 and the first pixel definition layer 26 are alternately arranged with each other. The first organic light-emitting diode layer 24 is disposed on the first reflective layer 23. The first transparent conductive layer 25 is disposed on the first organic light-emitting diode layer 24 and the first pixel definition layer 26. The first pixel definition layer 26 is disposed between two adjacent top emission-type light-emitting devices 20.

As shown in FIG. 1, the first reflective layer 23 is made of a light reflective material such as an aluminum metal layer, or a composite layer composed of indium tin oxide (ITO) and silver metal. The first transparent conductive layer 25 is made of a transparent material, such as an ultra-thin magnesium (Ag) and silver (Ag) alloy, ITO, indium zinc oxide (IZO), or the like. The first reflective layer 23 is electrically connected to the first thin film transistor 21. The first reflective layer 23 and the first transparent conductive layer 25 are respectively disposed on both sides of the first organic light-emitting diode layer 24, such that the first reflective layer 23 serves as an anode of the top emission-type light-emitting device 20, and the first transparent conductive layer 25 serves as a cathode of the top emission-type light-emitting device 20. Upon application of a certain voltage, electrons and holes are injected and migrated from the first transparent conductive layer 25 and the first reflective layer 23 to the first organic light-emitting diode layer 24. Then, the electrons and the holes are combined to form excitons in the first organic light-emitting diode layer 24 to excite luminescent molecules in the first organic light-emitting diode layer 24, thereby emitting light toward a light emission direction 2.

As shown in FIG. 1, each of the bottom emission-type light-emitting devices 30 includes a second thin film transistor 31, a second passivation layer 32, a second transparent conductive layer 33, a second organic light-emitting diode layer 34, a second reflective layer 35, and a second pixel definition layer 36. The second thin film transistor 31 is disposed on the second side 12 of the transparent substrate 10. The second passivation layer 32 is disposed on the second thin film transistor 31 and the transparent substrate 10. The second transparent conductive layer 33 and the second pixel definition layer 36 are both disposed on the second passivation layer 32, and the second reflective layer 35 and the second pixel definition layer 36 are alternately arranged with each other. The second organic light-emitting diode layer 34 is disposed on the second transparent conductive layer 33. The second reflective layer 35 is disposed on the second organic light-emitting diode layer 34 and the second pixel definition layer 36. The second pixel definition layer 36 is disposed between two adjacent bottom emission-type light-emitting devices 30.

As shown in FIG. 1, the second reflective layer 35 is made of a light reflective material such as an aluminum metal layer, or a composite layer composed of indium tin oxide (ITO) and silver metal. The second transparent conductive layer 33 is made of a transparent material, such as an ultra-thin magnesium (Ag) and silver (Ag) alloy, ITO, indium zinc oxide (IZO), or the like. The second transparent conductive layer 33 is electrically connected to the second thin film transistor 31. The second transparent conductive layer 33 and the second reflective layer 35 are respectively disposed on both sides of the second organic light-emitting diode layer 34, such that the second transparent conductive layer 33 serves as an anode of the bottom emission-type light-emitting device 30, and the second reflective layer 35 serves as a cathode of the bottom emission-type light-emitting device 30. Upon application of a certain voltage, electrons and holes are injected and migrated from the second transparent conductive layer 33 and the second reflective layer 35 to the second organic light-emitting diode layer 34. Then, the electrons and the holes are combined to form excitons in the second organic light-emitting diode layer 34 to excite luminescent molecules in the second organic light-emitting diode layer 34, thereby emitting light toward the light emission direction 2. That is, the light emission direction 2 of the top emission-type light-emitting device 20 is the same as the light emission direction 2 of the bottom emission-type light-emitting device 30.

As shown in FIG. 1, at least a portion the second thin film transistor 31 of the bottom emission-type light-emitting device 30 is overlapped with the first thin film transistor 21 of the top emission-type light-emitting device 20 in a vertical direction (parallel to the light emission direction 2). That is, an orthographic projection of the second thin film transistor 31 of the bottom emission-type light-emitting device 30 on the top emission-type light-emitting device 20 overlaps at least a portion of the first thin film transistor 21. Preferably, an orthographic projection of the second thin film transistor 31 of the bottom emission-type light-emitting device 30 on the transparent substrate 10 is prevented from mutually overlapping on another orthographic projection of the second transparent conductive layer 33 on the transparent substrate 10, or they only overlap each other in a portion 37 that are connected. Preferably, an orthographic projection of the first reflective layer 23 of the top emission-type light-emitting device 20 on the transparent substrate 10 is prevented from mutually overlapping on another orthographic projection of the second reflective layer 35 of the bottom emission-type light-emitting device 30 on the transparent substrate 10. By the above design, the organic light-emitting diode display 1 of the present disclosure forms an AMOLED display panel integrating structures of a top emission-type device and a bottom emission-type device. Also, the effective light-emitting areas of the plurality of top emission-type light-emitting devices 20 and the plurality of bottom emission-type light-emitting devices 30 are alternately arranged with each other. It should be noted that the top emission-type light-emitting device 20 and the bottom emission-type light-emitting device 30 emit light to the same side of the display panel, that is, the emission direction 2 of the top emission-type light-emitting device 20 is the same as the emission direction 2 of the bottom emission-type light-emitting device 30, so that light from either the top emission-type light-emitting device 20 or the bottom emission-type light-emitting device 30 can emit to an outside. Therefore, a ratio of the effective light-emitting area of the organic light-emitting diode display 1 can be effectively increased, and an aperture and a pixel density can be greatly improved. On the other hand, due to the increase of the aperture and the pixel density, current values required to be applied to respective sub-pixels (i.e., each top emission-type light-emitting device 20 or each bottom emission-type light-emitting device 30) of the organic light-emitting diode display 1 of the present disclosure will be significantly lower than those of the prior art display panel in a case that the same display brightness is required. Since a magnitude of the current applied by the OLED display during operation directly limits its lifespan, the organic light-emitting diode display 1 of the present disclosure will exhibit a longer lifespan.

In conclusion, the present disclosure forms the organic light-emitting diode display 1 into an AMOLED display panel integrating structures of a top emission-type device and a bottom emission-type device. When the organic light-emitting diode display 1 is in operation, the top emission-type light-emitting device 20 and the bottom emission-type light-emitting device 30 on both sides of the transparent substrate 10 emit light in the same direction. The organic light-emitting diode display 1 of the present disclosure has a higher aperture and a doubling of a pixel density as compared to the prior art,

The above descriptions are merely preferable embodiments of the present disclosure, and are not intended to limit the scope of the present disclosure. Any modification or replacement made by those skilled in the art without departing from the spirit and principle of the present disclosure should fall within the protection scope of the present disclosure.

What is claimed is:

1. An organic light-emitting diode display, comprising:
a transparent substrate comprising a first side and a second side opposite to the first side;
a top emission-type light-emitting device disposed on the first side of the transparent substrate, wherein the top emission-type light-emitting device comprises:
a first thin film transistor;
a first passivation layer disposed on the first thin film transistor;
a first reflective layer disposed on the first passivation layer and electrically connected to the first thin film transistor;
a first organic light-emitting diode layer disposed on the first reflective layer; and
a first transparent conductive layer disposed on the first organic light-emitting diode layer; and
a bottom emission-type light-emitting device disposed on the second side of the transparent substrate, wherein the bottom emission-type light-emitting device comprises:
a second thin film transistor;
a second passivation layer disposed on the second thin film transistor;
a second transparent conductive layer disposed on the second passivation layer and electrically connected to second thin film transistor;
a second organic light-emitting diode layer disposed on the second transparent conductive layer; and
a second reflective layer disposed on the second organic light-emitting diode layer;
wherein an orthographic projection of the second thin film transistor of the bottom emission-type light-emitting device on the top emission-type light-emitting device overlaps at least a portion of the first thin film transistor.

2. The organic light-emitting diode display as claimed in claim 1, wherein a light emission direction of the top emission-type light-emitting device is the same as that of the bottom emission-type light-emitting device.

3. The organic light-emitting diode display as claimed in claim 1, wherein the first reflective layer serves as an anode of the top emission-type light-emitting device, and the first transparent conductive layer serves as a cathode of the top emission-type light-emitting device.

4. The organic light-emitting diode display as claimed in claim 1, further comprising a plurality of top emission-type light-emitting devices and a first pixel definition layer disposed between two adjacent top emission-type light-emitting devices.

5. The organic light-emitting diode display as claimed in claim 1, wherein the second transparent conductive layer serves as an anode of the bottom emission-type light-emitting device, and the second reflective layer serves as a cathode of the bottom emission-type light-emitting device.

6. The organic light-emitting diode display as claimed in claim 1, wherein an orthographic projection of the second thin film transistor on the transparent substrate is prevented from mutually overlapping on another orthographic projection of the second transparent conductive layer on the transparent substrate, or they only overlap each other in a portion that are connected.

7. The organic light-emitting diode display as claimed in claim 1, further comprising a plurality of bottom emission-type light-emitting devices and a second pixel definition layer disposed between two adjacent bottom emission-type light-emitting devices.

8. The organic light-emitting diode display as claimed in claim 1, wherein an orthographic projection of the first reflective layer on the transparent substrate is prevented from mutually overlapping on another orthographic projection of the second reflective layer on the transparent substrate.

9. An organic light-emitting diode display, comprising:
a transparent substrate comprising a first side and a second side opposite to the first side;
a top emission-type light-emitting device disposed on the first side of the transparent substrate, wherein the top emission-type light-emitting device comprises a first thin film transistor, and
a bottom emission-type light-emitting device disposed on the second side of the transparent substrate, wherein the bottom emission-type light-emitting device comprises a second thin film transistor, and an orthographic projection of the second thin film transistor of the bottom emission-type light-emitting device on the top emission-type light-emitting device overlaps at least a portion of the first thin film transistor.

10. The organic light-emitting diode display as claimed in claim 9, wherein a light emission direction of the top emission-type light-emitting device is the same as that of the bottom emission-type light-emitting device.

11. The organic light-emitting diode display as claimed in claim 9, wherein the top emission-type light-emitting device further comprises:
a first passivation layer disposed on the first thin film transistor;
a first reflective layer disposed on the first passivation layer and electrically connected to the first thin film transistor;
a first organic light-emitting diode layer disposed on the first reflective layer; and
a first transparent conductive layer disposed on the first organic light-emitting diode layer.

12. The organic light-emitting diode display as claimed in claim 11, wherein the first reflective layer serves as an anode of the top emission-type light-emitting device, and the first transparent conductive layer serves as a cathode of the top emission-type light-emitting device.

13. The organic light-emitting diode display as claimed in claim 11, further comprising a plurality of top emission-type light-emitting devices and a first pixel definition layer disposed between two adjacent top emission-type light-emitting devices.

14. The organic light-emitting diode display as claimed in claim 9, wherein the bottom emission-type light-emitting device further comprises:
a second passivation layer disposed on the second thin film transistor;
a second transparent conductive layer disposed on the second passivation layer and electrically connected to second thin film transistor;
a second organic light-emitting diode layer disposed on the second transparent conductive layer; and
a second reflective layer disposed on the second organic light-emitting diode layer.

15. The organic light-emitting diode display as claimed in claim 14, wherein the second transparent conductive layer serves as an anode of the bottom emission-type light-emitting device, and the second reflective layer serves as a cathode of the bottom emission-type light-emitting device.

16. The organic light-emitting diode display as claimed in claim 14, wherein an orthographic projection of the second thin film transistor on the transparent substrate is prevented from mutually overlapping on another orthographic projection of the second transparent conductive layer on the transparent substrate, or they only overlap each other in a portion that are connected.

17. The organic light-emitting diode display as claimed in claim 14, further comprising a plurality of bottom emission-type light-emitting devices and a second pixel definition layer disposed between two adjacent bottom emission-type light-emitting devices.

18. The organic light-emitting diode display as claimed in claim 9, wherein the top emission-type light-emitting device further comprises a first reflective layer, and the bottom emission-type light-emitting device further comprises a second reflective layer, and an orthographic projection of the first reflective layer on the transparent substrate is prevented from mutually overlapping on another orthographic projection of the second reflective layer on the transparent substrate.
